(19) United States
(12) Patent Application Publication
(10) Pub. No.: US 2025/0133725 A1
(43) Pub. Date: Apr. 24, 2025

(54) DRAM DEVICE HAVING SUB 4F2 STRUCTURE

(71) Applicant: Taesung Environmental Research Institute CO., LTD., Ulsan (KR)

(72) Inventors: Gi Yeol YUN, Ulsan (KR); Seok Man Kim, Ulsan (KR); Chai Rok Lim, Ulsan (KR); Hyun Dong Woo, Ulsan (KR); Hyeok Je Jeong, Gimhae-si (KR); Myung Kon Jo, Ulsan (KR)

(73) Assignee: Taesung Environmental Research Institute CO., LTD., Ulsan (KR)

(21) Appl. No.: 18/665,643

(22) Filed: May 16, 2024

(30) Foreign Application Priority Data
Oct. 20, 2023 (KR) 10-2023-0141180

(51) Int. Cl. H10B 12/00

(52) U.S. Cl. CPC H10B 12/482; H10B 12/315; H10B 12/488

(57) ABSTRACT

Provided is a semiconductor device including: a substrate; a plurality of bit lines located on the substrate and disposed in parallel in a first horizontal direction at predetermined intervals; a plurality of channel patterns respectively arranged on the bit lines in a zigzag pattern along both side edges of the bit lines, and each extending in a vertical direction; a plurality of first word lines commonly connected to the plurality of channel patterns arranged along one side edges of the bit lines; a plurality of second word lines commonly connected to the plurality of channel patterns arranged along the other side edges of the bit lines, disposed in parallel in the second horizontal direction at predetermined intervals, and disposed at a different height from the first word lines; and a gate insulating pattern located between the plurality of channel patterns and the plurality of first or second word lines.

### CROSS-REFERENCE TO RELATED APPLICATION

This application claims priority to and the benefit of Korean Patent Application No. 10-2023-0141180, filed on Oct. 20, 2023, the disclosure of which is incorporated herein by reference in its entirety.

### BACKGROUND

### 1. Field of the Invention

The present invention relates to a semiconductor device, and more specifically, to a semiconductor device including a vertical channel transistor.

### 2. Discussion of Related Art

As the degree of integration of semiconductor memory devices increases, a cell structure is changing from 8F2 and 6F2 to 4F2 to reduce the area occupied by each unit cell in two dimensions. Thus, in response to the reduction in unit cell area, various methods of forming components such as transistors, bit lines, word lines, and capacitors have been proposed. Specifically, in order to implement the 4F2 cell structure, a semiconductor device including a vertical channel transistor which induces a vertical channel by disposing a source and a drain vertically has been proposed (Non-Patent Document 1).

Meanwhile, in the field of semiconductor devices, in order to increase capacity per unit area, continuous progress is being made toward reducing a minimum feature size F and pursuing smaller cell layouts. However, recently, an increase in capacity per unit area through the reduction in minimum feature size F has reached a physical limit, and accordingly, it is difficult to expect an increase in capacity per unit area anymore in the semiconductor device in Non-Patent Document 1.

### RELATED-ART DOCUMENT

### Non-Patent Document

(Non-Patent Document 1) Chung et al., “Novel 4F2 DRAM Cell with Vertical Pillar Transistor (VPT),” 2011 Proceedings of the European Solid-State Device Research Conference (ESSDERC), 2011

### SUMMARY OF THE INVENTION

The present invention is directed to providing a vertical channel transistor capable of increasing capacity per unit area and a semiconductor device including the same.

According to an aspect of the present invention, there is provided a semiconductor device including: a substrate; a plurality of bit lines located on the substrate and disposed in parallel in a first horizontal direction at predetermined intervals; a plurality of channel patterns respectively arranged on the bit lines in a zigzag pattern along both side edges of the bit line, and each extending in a vertical direction; a plurality of first word lines commonly connected to the plurality of channel patterns arranged along one side edges of the bit lines and disposed in parallel in a second horizontal direction substantially perpendicular to the first horizontal direction at predetermined intervals; a plurality of second word lines commonly connected to the plurality of channel patterns arranged along the other side edges of the bit lines, disposed in parallel in the second horizontal direction at predetermined intervals, and disposed at a different height from the first word lines; and a gate insulating pattern located between the plurality of channel patterns and the plurality of first or second word lines.

In one embodiment, the first and second word lines may be alternately arranged in the first horizontal direction.

In one embodiment, the first and second word lines may be formed of different materials.

In one embodiment, the semiconductor device may further include spacers provided on side walls of the first and second word lines.

In one embodiment, each of the plurality of channel patterns may include an upper electrode and a lower electrode, and the lower electrode may be in contact with the bit line.

In one embodiment, the semiconductor device may further include a gate conductive pattern provided between the word line and the gate insulating pattern.

In one embodiment, the semiconductor device may further include a plurality of capacitors respectively disposed on the plurality of channel patterns.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a perspective view of a vertical channel transistor according to one embodiment of the present invention;

FIG. 2 is a cross-sectional view taken along line A-A′ in FIG. 1;

FIG. 3 is a cross-sectional view taken along line B-B′ in FIG. 1; and

FIG. 4 is a perspective view of a semiconductor device including the vertical channel transistor according to one embodiment of the present invention.

FIG. 5A is a top view of a DRAM device including vertical channel transistors of a conventional 4F2 structure.

FIG. 5B is a top view of a DRAM device comprising vertical channel transistors.

### DETAILED DESCRIPTION OF EXEMPLARY EMBODIMENTS

Hereinafter, one aspect of the present specification will be described with reference to the accompanying drawings. However, the disclosed items of the present specification may be implemented in various different forms, and thus are not limited to the embodiments described herein.

Throughout the present specification, a case in which one part is “connected to” another part includes not only a case in which the one part is “directly connected to” another part but also a case in which the one part is “indirectly connected to” another part with another member therebetween. Further, a case in which a certain member is located “on,” “at an upper portion,” “at an upper end,” “under,” “at a lower portion,” or “at a lower end” includes not only a case in which the certain member is in contact with another member, but also a case in which still another member is present between the two members.

Throughout the present specification, a case in which a certain part “includes” a certain component means that other components may be further included, rather than excluding other components, unless otherwise specified.

Embodiments described in the present specification will be described with reference to cross-sectional views and/or schematic diagrams which are ideal exemplary views of the present invention. Further, the same reference numerals refer to the same components throughout the specification. In this case, detailed descriptions of known functions and configurations which may obscure the gist of the present invention are omitted. Further, in each drawing shown in the present invention, each component may be shown in a somewhat enlarged or downsized form in consideration of convenience of description.

In addition, the embodiments of the present invention are not limited to the specific forms shown, and also include changes in forms generated according to a manufacturing process.

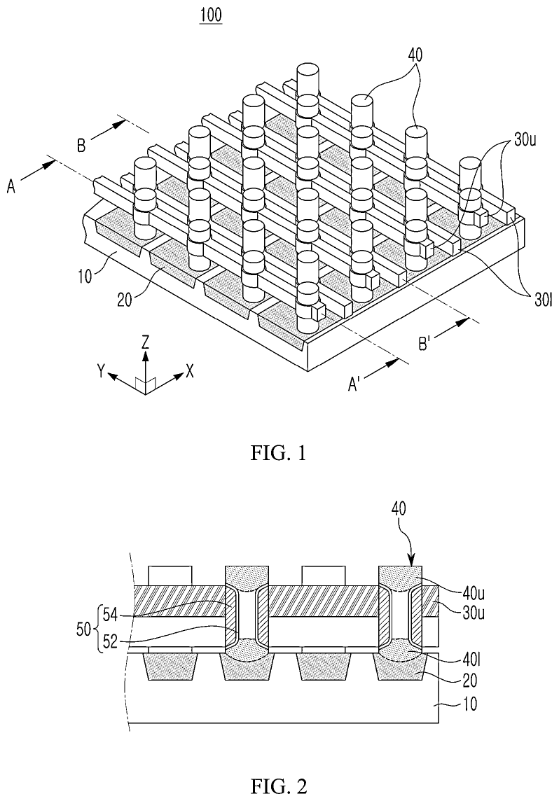

FIG. 1 is a perspective view schematically illustrating a vertical channel transistor according to one embodiment of the present invention.

Referring to FIG. 1, a vertical channel transistor 100 according to one embodiment of the present invention includes a substrate 10, a plurality of bit lines 20 located on the substrate 10 and disposed in parallel in a first horizontal direction at predetermined intervals, a plurality of channel patterns 40 respectively arranged on the bit lines 20 in a zigzag pattern along both side edges of the bit lines 20, and each extending in a vertical direction, a plurality of first word lines 30u commonly connected to the plurality of channel patterns 40 arranged along one side edges of the bit lines 20 and disposed in parallel in a second horizontal direction substantially perpendicular to the first horizontal direction at predetermined intervals, a plurality of second word lines 30l commonly connected to the plurality of channel patterns 40 arranged along the other side edges of the bit lines 20, disposed in parallel in the second horizontal direction at predetermined intervals, and disposed at a different height from the first word lines 30u, and a gate insulating pattern (not shown) located between the plurality of channel patterns 40 and the plurality of first or second word lines 30u or 30l.

In the vertical channel transistor 100 according to one embodiment of the present invention, the plurality of bit lines 20 and the plurality of first and second word lines 30u and 30l are arranged to cross each other. Each bit line 20 may be provided to extend in the first horizontal direction (for example, an x-axis direction), and each of the first and second word lines 30u and 30l may be provided to extend in the second horizontal direction (for example, a y-axis direction) crossing the first horizontal direction.

The plurality of channel patterns 40 extending in the vertical direction (for example, a z-direction) are respectively disposed at points where the plurality of bit lines 20 and the plurality of first and second word lines 30u and 30l cross.

Electrodes (not shown) may be respectively formed at the top and bottom of the plurality of channel patterns 40, a gate (not shown) may be formed to surround side surfaces between an upper electrode and a lower electrode, and the gate may be composed of the gate insulating pattern and a gate conductive pattern.

The plurality of channel patterns 40 are lined up on one bit line 20 in the first horizontal direction (for example, the x-axis direction), and are arranged in a zigzag manner along both edges.

In a conventional vertical channel transistor, since a plurality of channel patterns are lined up in a row on one bit line, there was a physical limit to increasing capacity per unit area.

However, in the present invention, as the plurality of channel patterns 40 are arranged in the zigzag manner along both edges of the bit line 20, there is an advantage in that capacity per unit area can be increased and the degree of integration can be improved even when a minimum feature size F is not reduced.

The first and second word lines 30u and 30l are disposed at different heights when viewed in a vertical cross-section.

For example, the first word lines 30u may be disposed at a higher position than the second word lines 30l, and the first and second word lines 30u and 30l may be alternately arranged in the first horizontal direction (for example, the x-axis direction).

The plurality of channel patterns 40 arranged along one side edges of the plurality of bit lines 20 may be commonly connected to the first word lines 30u, and the plurality of channel patterns 40 arranged along the other side edges of the plurality of bit lines 20 may be commonly connected to the second word lines 30l.

In the conventional vertical channel transistor, since a plurality of word lines are arranged in parallel at substantially the same height, there was a physical limit to increasing the capacity per unit area.

However, in the present invention, as adjacent word lines are disposed at different heights, the minimum feature size F may be easily reduced, and as a result, there is an advantage in that the capacity per unit area can be increased and the degree of integration can be improved

The first and second word lines 30u and 30l may be independently formed of at least one material among a metal, a semiconductor, and an alloy, may be formed of the same material, and may also be formed of different materials.

Spacers (not shown) may be provided on side walls of the first and second word lines 30u and 30l, and the spacers may serve to prevent contact with other channel patterns 40 that are not interconnected by the first and second word lines 30u and 30l.

FIG. 2 is a cross-sectional view taken along line A-A′ in FIG. 1.

Referring to FIG. 2, the vertical channel transistor 100 includes the substrate 10, and the plurality of channel patterns 40 arranged along one side edges of the bit lines 20.

The substrate may include, for example, group IV semiconductor materials such as silicon (Si), germanium (Ge), silicon germanium (SiGe), and silicon carbide (SiC), group III-V semiconductor materials such as gallium arsenide (GaAs), indium arsenide (InAs), and indium phosphide (InP), an oxide semiconductor, a nitride semiconductor, a nitride oxide semiconductor, or the like. Specifically, the substrate may be a silicon substrate doped with n-type impurities, but is not limited thereto.

Each of the plurality of channel patterns 40 may be provided to extend substantially vertically from the substrate 10. Here, each channel pattern 40 may be provided to protrude substantially vertically from an upper surface of the substrate 10. Each channel pattern 40 is formed integrally with the substrate 10, and thus may include the same semiconductor material as the substrate 10.

Each of the plurality of channel patterns 40 may include a source region as an upper electrode 40u and a drain region as a lower electrode 40l. The lower electrode 40l may be electrically connected to the bit line 20, and the upper electrode 40u may be electrically connected to a capacitor (not shown), which will be described below. The positions of the source region and the drain region may be changed as needed, and the upper electrode 40u may function as the drain region and the lower electrode 40l may function as the source region.

A gate 50 is formed between the upper electrode and the lower electrode to surround the side surfaces of the channel pattern 40, and the gate 50 may be composed of a gate insulating pattern 52 and a gate conductive pattern 54.

According to one embodiment, at least a portion of each channel pattern 40 may be in direct contact with the substrate 10, and in this case, a back bias may be transmitted to each channel pattern 40 to suppress a phenomenon called a floating body effect. The contact region between each channel pattern 40 and the substrate 10 is not specifically limited, but for example, may be an outer portion of each channel pattern 40.

The bit lines 20 may be provided to extend along the first horizontal direction (for example, the x-axis direction) under the lower electrodes 40l, and each bit line 20 may electrically connect the lower electrodes 40l arranged along the first horizontal direction. The bit line 20 is formed in the substrate 10, and thus may include the same semiconductor material as the substrate 10.

Each of the plurality of first word lines 30u is provided to correspond to the gate 50 formed on the side surfaces of the channel pattern 40. Specifically, each first word line 30u may be provided to be connected to an upper end portion of the gate 50.

The first word line 30u may include a conductive material. For example, the first word line 30u may include at least one or more among a metal, a semiconductor, and an alloy. Specifically, the first word line 30u may include one or more metals selected from the group consisting of aluminum, tungsten, molybdenum, titanium, and tantalum, and one or more semiconductors selected from the group consisting of a group IV semiconductor, a group III-V semiconductor, an oxide semiconductor, a nitride semiconductor, and a nitride oxide semiconductor, but is not limited thereto.

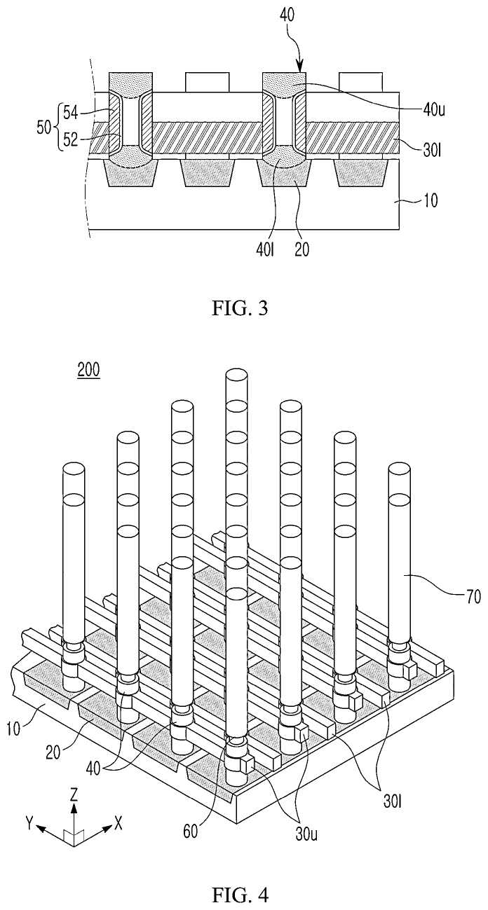

FIG. 3 is a cross-sectional view taken along line B-B′ in FIG. 1.

Referring to FIG. 3, the vertical channel transistor 100 includes the substrate 10, and the plurality of channel patterns 40 arranged along the other side edges of the bit lines 20.

The plurality of channel patterns 40 arranged along the other side edges of the plurality of bit lines 20 are commonly connected to the second word lines 30l, and specifically, each second word line 30l may be provided to be connected to a lower end portion of the gate 50.

The second word lines 30l are disposed at a different height from the first word lines 30u when viewed in a vertical cross-section, and specifically, the second word lines 30l are disposed at lower positions than the first word lines 30u. As adjacent first and second word lines 30u and 30l are disposed at different heights, the minimum feature size F may be easily reduced, and as a result, there is an advantage in that the capacity per unit area can be increased and the degree of integration can be improved.

FIG. 4 is a perspective view schematically illustrating a semiconductor device including the vertical channel transistor according to one embodiment of the present invention.

Referring to FIG. 4, a capacitor 70 may be connected to an upper portion of the vertical channel transistor 100, and accordingly, a semiconductor device 200 such as a dynamic random access memory (DRAM) may be implemented.

The capacitor 70 may be electrically connected to the channel pattern 40, and a contact plug 60 may be further included between the capacitor 70 and the channel pattern 40. The vertical channel transistor 100 may be used in a non-memory device such as a central processing unit (CPU) in addition to the memory described above.

In the present invention, a method of manufacturing a vertical channel transistor and a semiconductor device including the same is not particularly limited, but for example, the vertical channel transistor and the semiconductor device may be manufactured using the following method.

On a substrate 10, a plurality of channel patterns 40 with electrodes 40u and 40l formed at the top and bottom thereof and extending in a substantially vertical direction are formed. The upper electrodes 40u of the plurality of channel patterns 40 may be, for example, source regions, and the lower electrodes 40l of the plurality of channel patterns 40 may be, for example, drain regions.

The plurality of channel patterns 40 may be arranged on a plane (for example, an xy plane) of the substrate 10 in a zigzag manner.

Next, gates 50 are formed to surround side surfaces between the upper electrodes 40u and the lower electrodes 40l of the plurality of channel patterns 40. The gate 50 may include a gate insulating pattern 52 and a gate conductive pattern 54. In this case, a vertical height of the gate 50 may be formed to be at least greater than the sum of vertical heights of first and second word lines 30u and 30l, which will be described below.

Next, a plurality of bit lines 20 are formed to commonly come into contact with the lower electrodes 40d of two adjacent rows of the plurality of channel patterns 40 arranged in a zigzag manner. Here, the bit line 20 may be formed in the first horizontal direction (for example, the x-axis direction).

Next, the plurality of first and second word lines 30u and 30l are formed to commonly come into contact with the gates 50 formed on the side surfaces of the plurality of channel patterns 40. Specifically, the plurality of first and second word lines 30u and 30l are formed so that the plurality of channel patterns 40 arranged along one side edges of the plurality of bit lines 20 are commonly connected to the first word lines 30u and the plurality of channel patterns 40 arranged along the other side edges of the plurality of bit lines 20 are commonly connected to the second word lines 30l. Here, the first and second word lines 30u and 30l may be formed in the second horizontal direction (for example, the y-axis direction).

Thereafter, the manufacture of the vertical channel transistor according to the present invention and the semiconductor device including the same may be completed by sequentially performing a series of known follow-up processes.

Hereinafter, the technical reasons why the minimum feature size F can be easily reduced as adjacent word lines are disposed at different heights in the present invention will be described in more detail.

In the field of DRAM devices, the minimum feature size F is an important factor that determines the integration and performance of the device. The minimum feature size refers to the smallest line width that can be drawn within a semiconductor circuit, typically the smallest of (1) the width of a word line, (2) the width of a bit line, (3) the spacing between adjacent word lines, and (4) the spacing between adjacent bit lines.

The smaller the minimum feature size F, the higher the transistor density of the semiconductor chip, the smaller the size of the chip, and the lower the power consumption, so technology advances in the field of DRAM devices have been directed toward adopting the smallest possible minimum feature size.

However, the minimum feature size is not arbitrarily reducible and is usually determined by the level of technological advancement at the time of manufacturing. Specifically, it is determined by the resolution power of the photolithography equipment and the quality and performance of the photoresist, etc.

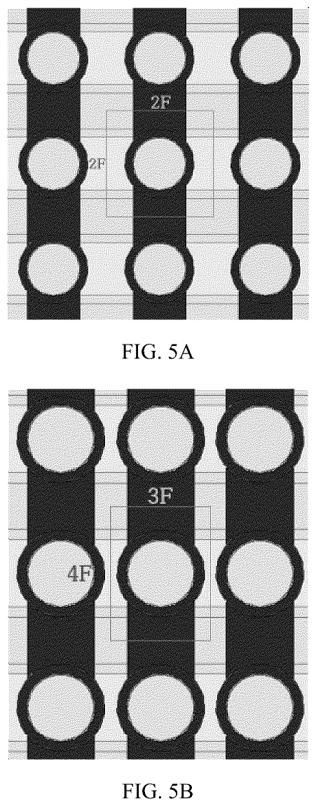

FIG. 5A is a top view of a DRAM device including vertical channel transistors of a conventional 4F2 structure. In FIG. 5A, (1) the width of a word line, (2) the width of a bit line, (3) the spacing between adjacent word lines, and (4) the spacing between adjacent bit lines are all set to F, resulting in a 4F2 structure.

FIG. 5B is a top view of a DRAM device comprising vertical channel transistors, wherein (3) the spacing between the adjacent word lines is reduced to half of (1) the width of the word line, (2) the width of the bit line, and (4) the spacing between adjacent bit lines. In this case, (3) the spacing between the adjacent word lines becomes a minimum feature size F, which is determined by the level of technological advancement at the time of manufacturing, resulting in an increase in the area of the unit cell (12F2=4F×3F). In other words, adjusting the spacing between the adjacent word lines to reduce the cell area is not desirable.

However, in the present invention, it is possible to adjust the spacing between adjacent first word line and second word line as long as the spacing between adjacent first word lines or adjacent second word lines is at least a minimum feature size F. Because word lines formed in different planes (i.e., different heights) are formed at different process steps, the minimum feature size F, which is determined by the level of technological advancement at the time of manufacturing, only affects word lines formed in the same plane (i.e., at the same height). The horizontal spacing between adjacent first and second word lines can theoretically be adjusted by up to ½F.

A semiconductor device according to one aspect of the present invention has an advantage of having an improved capacity per unit area compared to the capacity per unit area generally achievable at the level of technological advancement at the time of manufacturing.

The effects of the one aspect of the present invention are not limited to the above-described effect, and should be understood as including all effects which can be inferred from configurations described in the detailed description of the present specification or claims.

The above description of the present specification is provided for illustrative purposes, and those skilled in the art should understand that the present specification may be easily modified into other specific forms without changing the technical spirit or essential features disclosed in the present specification. Accordingly, the above-described embodiments should be understood as being exemplary and not limiting. For example, each component described as a singular form may be implemented in a distributed form, and similarly, components described as a distributed form may also be implemented in a combined form.

The scope of the present specification is indicated by the following claims, and all changes or modifications derived from the meaning and the scope of the claims and equivalents thereof should be understood as being within the scope of the present specification.

### LIST OF REFERENCE NUMERALS

10: substrate
20: bit line
30u: first word line
30l: second word line
40: channel pattern
40l: lower electrode
40u: upper electrode
50: gate
52: gate insulating pattern
54: gate conductive pattern
60: contact plug
70: capacitor
100: vertical channel transistor
200: semiconductor device

What is claimed is:

1. A semiconductor device comprising:
a substrate;
a plurality of bit lines located on the substrate and disposed in parallel in a first horizontal direction at predetermined intervals;
a plurality of channel patterns respectively arranged on the bit lines in a zigzag pattern along both side edges of the bit line, and each extending in a vertical direction;
a plurality of first word lines commonly connected to the plurality of channel patterns arranged along one side edges of the bit lines and disposed in parallel in a second horizontal direction substantially perpendicular to the first horizontal direction at predetermined intervals;
a plurality of second word lines commonly connected to the plurality of channel patterns arranged along the other side edges of the bit lines, disposed in parallel in the second horizontal direction at predetermined intervals, and disposed at a different height from the first word lines; and
a gate insulating pattern located between the plurality of channel patterns and the plurality of first or second word lines.

2. The semiconductor device of claim 1, wherein the first and second word lines are alternately arranged in the first horizontal direction.

3. The semiconductor device of claim 1, wherein the first and second word lines are formed of different materials.

4. The semiconductor device of claim 1, further comprising spacers provided on side walls of the first and second word lines.

5. The semiconductor device of claim 1, wherein:
each of the plurality of channel patterns includes an upper electrode and a lower electrode; and
the lower electrode is in contact with the bit line.

6. The semiconductor device of claim 1, further comprising a gate conductive pattern provided between the word line and the gate insulating pattern.

7. The semiconductor device of claim 1, further comprising a plurality of capacitors respectively disposed on the plurality of channel patterns.
